(19) United States
(12) Patent Application Publication
(10) Pub. No.: US 2008/0239666 A1
(43) Pub. Date: Oct. 2, 2008

(54) FAN MODULE

(75) Inventors: Deborah H. Heller, Raleigh, NC (US); Jeffrey R. McClellan, Raleigh, NC (US); James Xavier Torok, Raleigh, NC (US); Dale Krisher, Wake Forest, NC (US)

Correspondence Address: FOGG & POWERS LLC, 10 SOUTH FIFTH STREET, SUITE 1000, MINNEAPOLIS, MN, 55402, US

(73) Assignee: ADC DSL SYSTEMS, INC., Eden Prairie, MN (US)

(21) Appl. No.: 11/692,368

(22) Filed: Mar. 28, 2007

(51) Int. Cl. H05K 7/20

(52) U.S. Cl. 361/695

(57) ABSTRACT

A fan module is disclosed. The fan module includes a base, at least one first side coupled to the base, and a plurality of fans coupled to the base. The plurality of fans are configured to substantially disperse thermal energy away from one or more electronic components in an enclosure to maintain a current temperature of the one or more electronic components below a critical temperature. The fan module further includes a connector mounted on the at least one first side and coupled to provide power to the plurality of fans. When one of the plurality of fans ceases to operate, the remaining fans in the plurality of fans continue to substantially disperse thermal energy away from the one or more electronic components while maintaining the current temperature below the critical temperature.

### RELATED APPLICATIONS

This application is related to commonly assigned U.S. patent application Ser. No. ______, (Attorney Docket No. 100.813US01), filed on even date herewith and entitled “PROGRAMMABLE HIGH SPEED CROSSBAR SWITCH” (the '813 Application). The '813 Application is incorporated herein by reference.

This application is also related to the following commonly assigned applications filed on even date herewith, each of which is incorporated herein by reference:

U.S. patent application Ser. No. ______, (Attorney Docket No. 100.816US01), entitled “AN APPARATUS FOR COOLING ELECTRONICS” (the '816 Application).

U.S. patent application Ser. No. ______, (Attorney Docket No. 100.818US01), entitled “FILTER ASSEMBLY” (the '818 Application).

### BACKGROUND

As additional service demands are placed on telecommunications systems, replacement of time-sensitive operations is occurring with electronically-configurable operations (that is, programmable electronic equipment). Increasingly, the additional service demands involve operating at optimal speeds to accommodate voice and data traffic on the system. Accommodating these traffic demands translates into additional energy created by one or more electronic components in the system. The one or more components are often contained in chassis at various locations throughout the system. Typically, these chassis include thermal conductors that are thermally coupled to each of the components within the chassis. The thermal conductors act as a heat sink, and excessive thermal energy (heat) is transferred away from each of the components, either to other areas in the chassis or from the chassis to an environment surrounding the chassis.

Alternative chassis cooling techniques include one or more fan assemblies directed to heat-sensitive (that is, critical) electronic components susceptible to high temperatures rather than an entire electronic circuit board assembly within the chassis. If a fan assembly fails, the chassis is inoperable without adequate cooling and requires immediate attention. A loss of any single chassis in the system due to inadequate cooling has significant economic and reliability implications.

### SUMMARY

The following specification discusses a fan module for cooling electronic components. Particularly, in one embodiment, a fan module is provided. The fan module includes a base, at least one first side coupled to the base, and a plurality of fans coupled to the base. The plurality of fans are configured to substantially disperse thermal energy away from one or more electronic components in an enclosure to maintain a current temperature of the one or more electronic components below a critical temperature. The fan module further includes a connector mounted on the at least one first side and coupled to provide power to the plurality of fans. When one of the plurality of fans ceases to operate, the remaining fans in the plurality of fans continue to substantially disperse thermal energy away from the one or more electronic components while maintaining the current temperature below the critical temperature.

### DRAWINGS

These and other features, aspects, and advantages are better understood with regard to the following description, appended claims, and accompanying drawings where:

FIG. 1 is a block diagram of an illustration of an electronic device;

FIG. 2 is an elevational view in cross-section illustrating a fan module for the device of FIG. 1;

FIG. 3 is an alternate elevational view in cross-section illustrating the fan module of FIG. 2;

FIG. 4 is a side elevational view of the fan module of FIG. 2;

FIG. 5 is a side elevational view of the fan module as shown from section A-A of FIG. 4;

FIG. 6 is a flow diagram illustrating an embodiment of a method for maintaining electronic component cooling for the device of FIG. 1; and

FIG. 7 is a flow diagram illustrating an embodiment of a method for cooling the device of FIG. 1 using the method of FIG. 6.

### DETAILED DESCRIPTION

The following detailed description describes at least one embodiment of a redundant cooling assembly that provides continuous cooling of electronic components in a programmable high speed crossbar switch for telecommunications networks. Advantageously, at least a portion of the cooling assembly substantially disperses any thermal energy created by one or more of the electronic components away from the switch and into an external environment. In the event that a single cooling assembly portion ceases to operate (that is, fails), the switch continues to operatively function in a fail safe cooling mode until at least the single failed cooling assembly portion is exchanged with a corresponding replacement cooling assembly portion.

The fail safe (that is, redundant) cooling mode allows replacement of at least the failed portion of the cooling assembly to be deferred while maintaining the electronic components below a critical temperature. In one implementation, the cooling assembly comprises an active replacement fan module with a plurality of individual fan assemblies. Moreover, one or more of the individual fan assemblies are removable for active replacement (that is, while the programmable high speed crossbar switch continues to operate). Installation of the active replacement fan module occurs without disrupting service to the network (that is, the active replacement fan module is instantly functional at the time of insertion to prevent any service disruptions to the network).

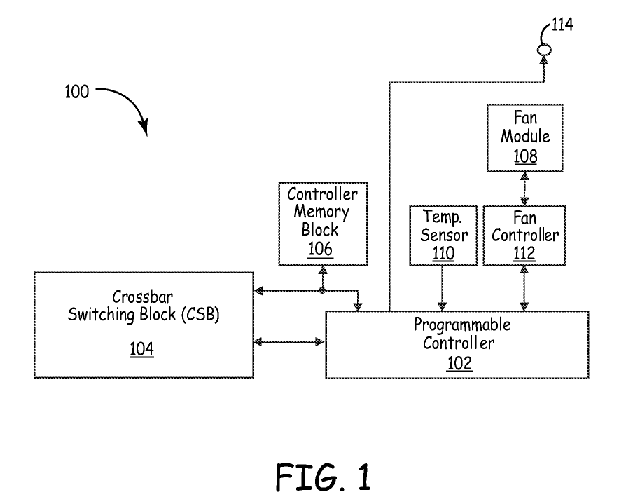

FIG. 1 is a block diagram of an illustration of an electronic device 100 with a fan module. The device 100 comprises a programmable controller 102, a crossbar switching block (CSB) 104 in communication with the programmable controller 102, and a controller memory block 106 responsive to the programmable controller 102. As described in the '813 Application, the CSB 104 is responsive to a plurality of digital signal path configuration commands. In one implementation, the programmable controller 102 is at least one of a microcontroller, an application-specific integrated circuit (ASIC), a field-programmable gate array (FPGA), a field-programmable object array (FPOA), and a programmable logic device (PLD).

The device 100 further comprises a fan controller 112, a fan module 108, and a temperature sensor 110, each of which is discussed in turn below. In one implementation, the device 100 further includes a diagnostic indicator 114. In the example embodiment of FIG. 1, the diagnostic indicator 114 is a light-emitting diode (LED) visible from an exterior panel of the device 100. The programmable controller 102 activates the diagnostic indicator 114 when at least one of the plurality of fans in the fan module 108 ceases to operate.

The fan controller 112, in communication with the programmable controller 102, controls the fan module 108 and monitors the fan module 108 for potential failures. In one implementation, the fan controller 112 is at least one of a microcontroller, an ASIC, an FPGA, an FPOA, and a PLD. The fan controller 112 activates at least a portion of the fan module 108 based on a prescribed temperature threshold level. The controller memory block 106 is operative to store the prescribed temperature threshold level. In one implementation, the prescribed temperature threshold level is at least 35° C. In the same and alternate implementations, the prescribed temperature threshold level is adjustable (that is, programmable). The temperature sensor 110 is responsive to the programmable controller 102 and records a temperature substantially surrounding one or more electronic components in the device 100. In the example embodiment of FIG. 1, the one or more electronics components include the programmable controller 102, the CSB 104, and the controller memory block 106. In one implementation, the fan controller 112 regulates a plurality of operating speeds for the fan module 108 based on each temperature the temperature sensor 110 records.

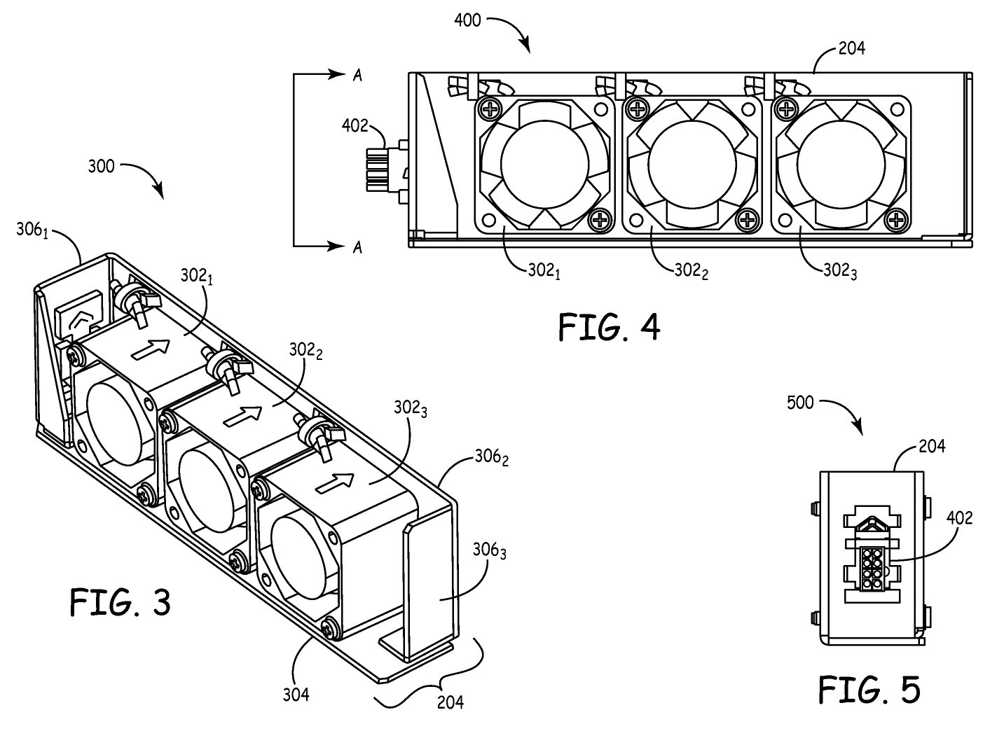

The fan module 108 is considered an active replacement fan module. The active replacement fan module comprises a plurality of modular fan assemblies within the fan module 108 (as described in further detail below with respect to FIG. 3). Each of the modular fan assemblies comprise a fan directed at the one or more electronic components in the device 100. The fan module 108 provides continuous cooling to the one or more electronic components without a disruption in service for the device 100. In one implementation, the fan module 108 comprises a floating connection for instant activation of the plurality of modular fan assemblies.

In operation, the temperature sensor 110 senses excessive thermal energy above the prescribed temperature threshold level. Based on the amount of thermal energy the temperature sensor 110 senses, the fan module 108 substantially disperses the thermal energy away from at least one component in the device 100 by directing one or more of the modular fan assemblies at the at least one component. The fan controller 112 and the fan module 108 provide continuous cooling for the device 100 without a disruption of service.

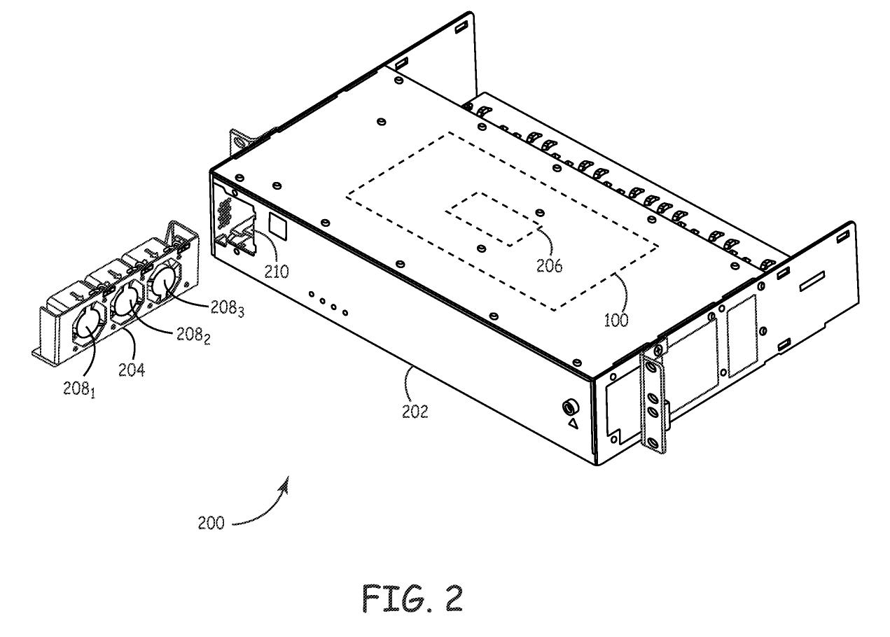

FIG. 2 is an elevational view 200 in cross-section illustrating a cooling assembly 204. In the example embodiment of FIG. 2, the cooling assembly 204 represents the fan module 108 of FIG. 1. FIG. 2 comprises an enclosure 202. FIG. 2 illustrates at least one example of installing the cooling assembly 204 within the enclosure 202. In the example embodiment of FIG. 2, the enclosure 202 encloses the device 100 and at least one thermal conductor 206 operatively coupled to the one or more components on the device 100. In one implementation, the at least one thermal conductor 206 is a heat sink.

The coooling assembly 204 further comprises openings 208₁ to 208₃. Each of the openings 208₁ to 208₃ are associated with at least one fan of the plurality of modular fan assemblies of the fan module 108. It is understood that the cooling assembly 204 is capable of accommodating any appropriate number of openings 208 (for example, one or more openings 208) for each of the modular fan assemblies of the fan module 108 in a single cooling assembly 204.

In one implementation, the cooling assembly 204 is serviceable without any tools. The cooling assembly 204 is accessed by removing a cover panel (not shown) and extracting the cooling assembly 204 from the enclosure 202. In one implementation, the cooling assembly 204 enters the enclosure 202 on a guide 210 until a floating blind-mate connector (shown in further detail below with respect to FIG. 5) mates with an internal connector in the enclosure 202. The cooling assembly 204 is a replaceable cooling assembly. The enclosure 202 will notify an operator via the diagnostic indicator 114 (FIG. 1) when at least a portion of the cooling assembly 204 ceases to operate. The device 100 continues to operate within design specifications in a fail safe mode until a replacement portion of the cooling assembly 204 is installed in the enclosure 202.

FIG. 3 is an alternate elevational view 300 in cross-section illustrating the cooling assembly 204 of FIG. 2. FIG. 3 illustrates the cooling assembly 204 as the active replacement fan module for the fan module 108 of FIG. 1. FIG. 3 comprises modular fan assemblies 302₁ to 302₃, a base 304, and sides 306₁ to 306₃. It is understood that the cooling assembly 204 is capable of accommodating any appropriate number of modular fan assemblies 302 and sides 306 (for example, one or more modular fan assemblies 302 and one or more sides 306) in a single cooling assembly 204. In one implementation, the modular fan assemblies 302₁ to 302₃ are operatively connected in parallel. In one or more alternate implementations, the modular fan assemblies 302₁ to 302₃ are operatively connected in series. In one implementation, the modular fan assemblies 302₁ to 302₃ comprise one or more variable-speed fan assemblies. The variable-speed fan assemblies 302₁ to 302₃ operate at one or more speeds depending on the number of variable-speed fan assemblies 302₁ to 302₃ currently operable in the enclosure 202. Moreover, the variable-speed fan assemblies 302₁ to 302₃ operate at one or more speeds depending on a temperature level recorded by the temperature sensor 110 in the device 100. As shown in FIGS. 4 and 5, the cooling assembly 204 further comprises a floating connection 402 for instant activation of the modular fan assemblies 302 in the enclosure 202.

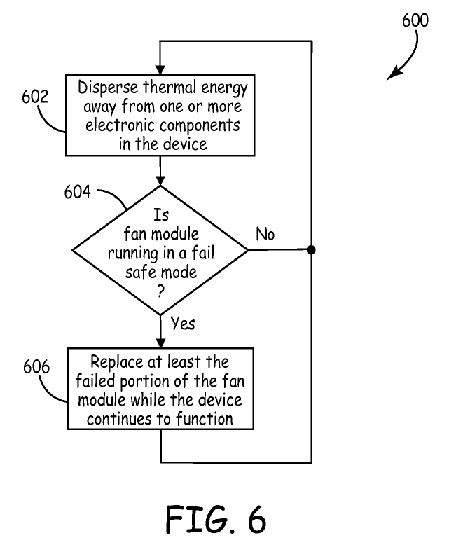

FIG. 6 is a flow diagram illustrating a method 600 for maintaining component cooling for the device 100 of FIG. 1. The method of FIG. 6 starts at block 602. The method 600 maintains a current temperature of the one or more electronic components in the device 100 below a critical temperature with the cooling assembly 204. When one of the plurality of fans (for example, the modular fan assembly 302₂ of FIG. 3) ceases to operate, the remaining fans in the plurality of fans (for example, the modular fan assemblies 302₁ and 302₃) continue to substantially disperse thermal energy away from the one or more electronic components in the device 100 while maintaining the current temperature below the critical temperature. The fan controller 112 ensures that the critical temperature does not exceed a prescribed component temperature operating range. As further discussed below, replacement of at least the failed portion of the cooling assembly 204 occurs without a disruption of service in the device 100.

At block 604, if the cooling assembly 204 is operating in a fail safe mode, the substantial dispersion of thermal energy continues at block 606 while replacing at least the failed portion of the cooling assembly 204 while the device 100 continues to function. In one implementation, the at least one thermal conductor 206 of FIG. 2 continues the substantial dispersion of thermal energy for the one or more components in the device 100. The cooling assembly 204 comprises the active replacement fan module (discussed above with respect to FIGS. 4 and 5). The active replacement fan module includes the floating connection 402 for instant activation of the replacement cooling assembly 204.

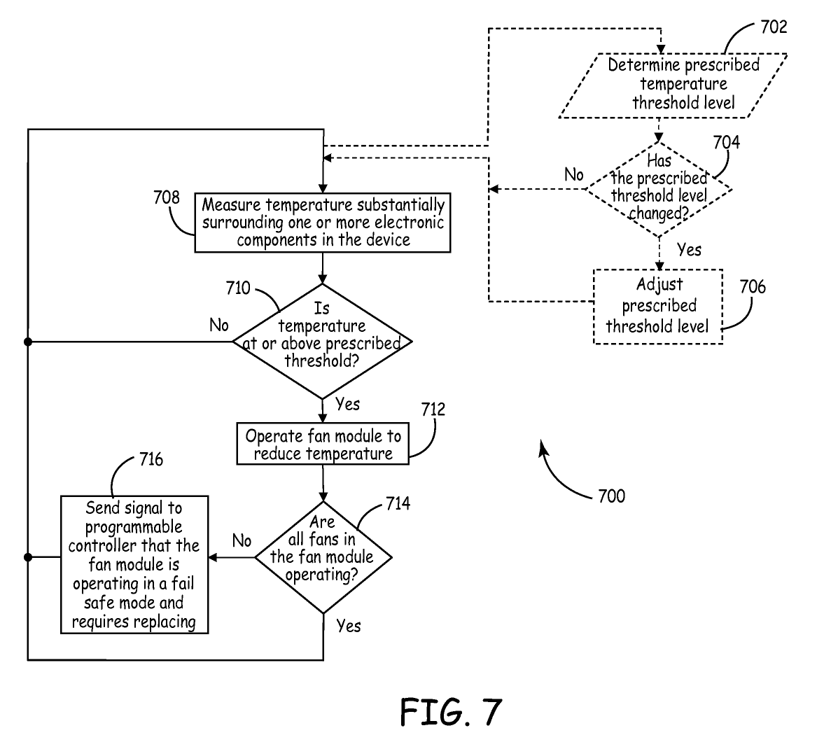

FIG. 7 is a flow diagram illustrating a method 700 for cooling the device 100 of FIG. 1. The method of FIG. 7 starts at block 702. The method 700 addresses substantially dispersing thermal energy away from one or more components in the device 100 with at least a portion of the cooling assembly 204 of FIG. 2. The cooling assembly 204 provides continuous cooling to the device 100. As further discussed below, replacement of at least the failed portion of the cooling assembly 204 occurs without a disruption of service in the device 100.

In one implementation, the block 700 determines a current prescribed temperature threshold level at block 702. At block 704, if the prescribed temperature threshold level has not changed (alternatively, the prescribed temperature threshold level is configured at a constant value), the method 700 continues at block 708. If the prescribed temperature threshold level has changed (block 706), the controller memory block 106 is updated and control logic in the fan controller 112 is adjusted. At block 708, the temperature sensor 110 measures a current temperature substantially surrounding one or more of the electronic components in the device 100. If the current temperature is at or above the prescribed temperature threshold level (block 710), the fan controller 112 automatically activates the cooling assembly 204 (that is, the fan module 108) at block 712 to substantially disperse thermal energy away from the one or more components in the device 100. The fan controller 112 controls and monitors a series of fans in the fan module 108. In the example embodiment of FIG. 7, the fan module 108 directs the series of fans at the one or more components in the device 100. If the current temperature is below the prescribed temperature threshold level, the method 700 resumes at block 702.

At block 714, the fan controller 112 senses if all of the fans in the fan module 108 are operating. If at least one fan in the fan module 108 is not operating, the fan controller 112 sends a signal to the programmable controller 102 that the fan module 108 is operating in a fail safe mode at block 716. In one implementation, the programmable controller 102 provides visual indication of the failure with the diagnostic indicator 114 that the fan module 108 requires replacing. The diagnostic indicator 114 provides a visual indication of the failure detected in the fan module 108. Continuously operating the device 100 in a fail safe cooling mode defers replacement of at least the failed portion of the fan module 108 while maintaining a current temperature in the device 100 below a critical temperature, as discussed above with respect to FIG. 6.

This description has been presented for purposes of illustration, and is not intended to be exhaustive or limited to the form (or forms) disclosed. Variations and modifications may occur, which fall within the scope of the following claims.

1. A fan module, comprising:
a base;
at least one first side coupled to the base;
a plurality of fans coupled to the base, the plurality of fans configured to substantially disperse thermal energy away from one or more electronic components in an enclosure to maintain a current temperature of the one or more electronic components below a critical temperature;
a connector mounted on the at least one first side and coupled to provide power to the plurality of fans; and
wherein when one of the plurality of fans ceases to operate, the remaining fans in the plurality of fans continue to substantially disperse thermal energy away from the one or more electronic components while maintaining the current temperature below the critical temperature.

2. The fan module of claim 1, and further comprising at least one second side.

3. The fan module of claim 2, wherein the at least one second side comprises a plurality of openings, each opening associated with at least one of the plurality of fans to enable air flow from the fan to flow towards the one or more electronic components.

4. The fan module of claim 1, wherein the critical temperature does not exceed a prescribed component temperature operating range.

5. The fan module of claim 1, wherein the enclosure comprises a diagonstic indicator to indicate when one of the plurality of fans ceases to operate.

6. The fan module of claim 1, wherein the plurality of fans are operatively connected in parallel.

7. The fan module of claim 1, wherein the plurality of fans are variable-speed fans that operate at one or more fan speeds depending on the number of fans currently operable in the fan module.

8. The fan module of claim 1, wherein the plurality of fans are variable-speed fans that operate at one or more fan speeds depending on the temperature level recorded by the temperature sensor.

9. The fan module of claim 1, wherein the connector comprises a floating connection for the plurality of fans within the at least one first side.

10. The fan module of claim 9, wherein the floating connection is a floating blind-mate connection that mates with an internal connector in the enclosure as the base advances into the enclosure.

11-22. (canceled)

23. A method for maintaining component temperature in an electronic device, the method comprising:
substantially dispersing thermal energy away from one or more components in the electronic device with at least a portion of a cooling assembly;
if a portion of the cooling assembly ceases to operate:
notifying an operator that the cooling assembly requires replacement, and
continuing to operate the cooling assembly while the portion of the cooling assembly is inoperable; and
while the electronic device continues to function, replacing at least the failed portion of the cooling assembly before the component temperature exceeds a critical temperature.

24. The method of claim 23, and further comprising automatically activating the cooling assembly based on a prescribed temperature threshold level.

25. The method of claim 23, and further comprising monitoring the cooling assembly for potential failures.

26. The method of claim 23, wherein substantially dispersing thermal energy away from the one or more components comprises directing a plurality of fans in the cooling assembly at the one or more components.

27. The method of claim 23, wherein notifying the operator that the cooling assembly requires replacement comprises activating a diagnostic indicator on the electronic device.

28-34. (canceled)
